(19) United States
(12) Patent Application Publication
(10) Pub. No.: US 2020/0142240 A1
(43) Pub. Date: May 7, 2020

(54) METHOD OF MANUFACTURING DISPLAY DEVICE AND DISPLAY DEVICE

(71) Applicant: Japan Display Inc., Minato-ku (JP)

(72) Inventor: Kenta KAJIYAMA, Minato-ku (JP)

(73) Assignee: Japan Display Inc., Minato-ku (JP)

(21) Appl. No.: 16/738,017

(22) Filed: Jan. 9, 2020

Related U.S. Application Data
(63) Continuation of application No. PCT/JP2018/014428, filed on Apr. 4, 2018.

(30) Foreign Application Priority Data
Jul. 10, 2017 (JP) 2017-134549

(51) Int. Cl. G02F 1/1345; H05K 1/02

(52) U.S. Cl. CPC G02F 1/13452; H05K 2201/10128; H05K 1/0259

(57) ABSTRACT

A method of manufacturing a display device according to an embodiment of the present invention includes: preparing a mother panel, the mother panel including a first display panel region and a second display panel region in contact with the first display panel region, a plurality of first terminals and a plurality of second terminals aligned along a boundary between the first and the second display panel region, a first connection line that crosses the boundary at a first crossing position and electrically connects one of the plurality of first terminals and one of the plurality of second terminals, and a second connection line that crosses the boundary at a second crossing position away from the first crossing position and electrically connects the one of the plurality of first terminals and one positioned next to the one of the plurality of second terminals; and cutting the mother panel at the boundary.

### CROSS-REFERENCE TO RELATED APPLICATION

This application is a continuation of International Application No. PCT/JP2018/014428, filed in the Japan Patent Office on Apr. 4, 2018, the entire contents of which are hereby incorporated by reference. This application claims priority from Japanese application JP2017-134549 filed on Jul. 10, 2017, the entire contents of which are hereby incorporated by reference.

### BACKGROUND OF THE INVENTION

### 1. Field of the Invention

The present invention relates to a method of manufacturing a display device and the display device.

### 2. Description of the Related Art

A plurality of terminals for inputting signals from the outside are provided at an edge portion of a display panel. These terminals are brought to the same potential by a short ring to prevent electrostatic discharge (ESD) during manufacturing.

Meanwhile, in a mother panel including a plurality of display panel regions cut out as a display panel, terminals may be provided on both sides of a planned cutting line. For example, in a mother panel of a division driving display panel in which terminals are allocated to two edge portions of upper and lower edge portions, the terminals are provided on both sides of the planned cutting line.

However, a conventional short ring cannot be applied to the mother panel in which the terminals are aligned on both sides of the planned cutting line. That is, in the conventional short ring, even if the mother panel is cut along the planned cutting line, the terminals cannot be electrically separated from each other in one of the two display panels to be cut off.

### SUMMARY OF THE INVENTION

The present invention has been made in view of the problems described above, and an object of the present invention is to provide a method of manufacturing a display device capable of electrically connecting the terminals even when a mother panel has the terminals aligned on both sides of a planned cutting line, and electrically separating the terminals along with the cutting of the mother panel, and the display device.

A method of manufacturing a display device according to an embodiment of the present invention includes: preparing a mother panel, the mother panel including a first display panel region and a second display panel region in contact with the first display panel region, a plurality of first terminals that are positioned at a first edge portion of the first display panel region adjacent to the second display panel region and aligned along a boundary between the first display panel region and the second display panel region, a plurality of second terminals that are positioned at a second edge portion of the second display panel region adjacent to the first display panel region and aligned along the boundary, a first connection line that crosses the boundary at a first crossing position and electrically connects one of the plurality of first terminals and one of the plurality of second terminals, and a second connection line that crosses the boundary at a second crossing position away from the first crossing position and electrically connects the one of the plurality of first terminals and one positioned next to the one of the plurality of second terminals; and cutting the mother panel at the boundary.

A display device according to an embodiment of the present invention includes: a plurality of first terminals that are aligned along an end surface at an edge portion of a display panel; a first connection line that is electrically connected to one of the plurality of first terminals, extends to the end surface, and is in contact with the end surface at a first position; and a second connection line that is electrically connected to the one of the plurality of first terminals, extends to the end surface, and is in contact with the end surface at a second position away from the first position.

### BRIEF DESCRIPTION OF THE DRAWINGS

FIG. 1 is a plan view illustrating a mother panel;

FIG. 2 is an enlarged diagram of two display panel regions included in the mother panel;

FIG. 3 is a circuit diagram of a short ring according to a first example, in which the vicinity of a planned cutting line is enlarged;

FIG. 4 is a diagram illustrating a state in which an FPC is attached to an edge portion of a display panel obtained by cutting out the display panel region illustrated in FIG. 3;

FIG. 5 is a cross-sectional view taken along line V-V illustrated in FIG. 4;

FIG. 6 is a cross-sectional view taken along line VI-VI illustrated in FIG. 4;

FIG. 7 is a circuit diagram of a short ring according to a second example, in which the vicinity of a planned cutting line is enlarged;

FIG. 8 is a diagram illustrating a state in which an FPC is attached to an edge portion of a display panel obtained by cutting out the display panel region illustrated in FIG. 7;

FIG. 9 is a circuit diagram illustrating a short ring according to a modification;

FIG. 10 is a circuit diagram illustrating a short ring according to a modification; and

FIG. 11 is a circuit diagram illustrating a short ring according to a modification.

### DETAILED DESCRIPTION OF THE INVENTION

Hereinafter, each embodiment of the present invention will be described with reference to the accompanying drawings. The disclosure is merely an example, and matters that those skilled in the art can easily conceive of appropriate modifications while maintaining the gist of the invention are naturally included in the scope of the present invention. The width, thickness, shape, and the like of each part may be schematically represented in the drawings as compared to the embodiment in order to clarify explanation, but are merely examples and do not limit the interpretation of the present invention. In the present specification and each drawing, elements similar to those described above with reference to the previous drawings are denoted by the same reference numerals, and detailed description thereof may be omitted as appropriate.

Furthermore, in the detailed description of the embodiment of the present invention, when prescribing the positional relationship between a certain component and another component, terms of “on”, “above” and “below” include not only a case where the other component is positioned immediately above or immediately below the certain component, but also a case where still another component is interposed therebetween, unless otherwise specified.

In the following description, an organic EL display device including an organic light emitting diode as a display element will be described as an example of a display device.

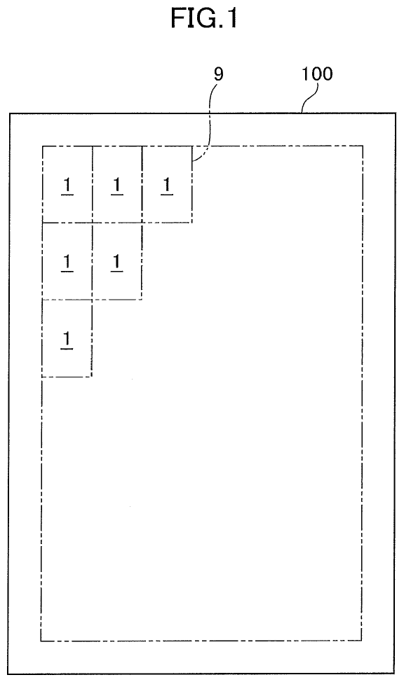

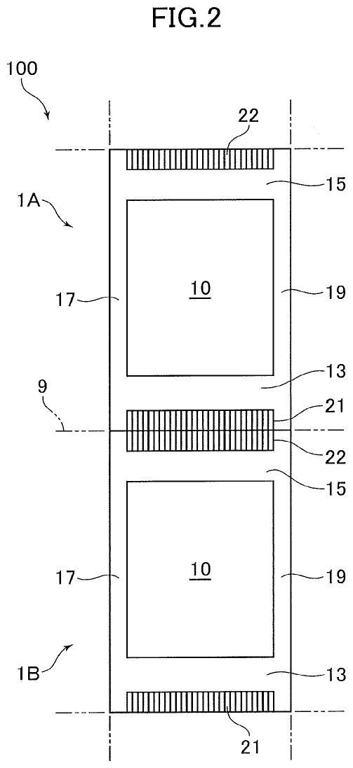

FIG. 1 is a plan view illustrating a mother panel 100. FIG. 2 is an enlarged view of two display panel regions 1A and 1B included in the mother panel 100. The mother panel 100 is prepared by a panel preparation process. In the panel preparation process, for example, an insulating film and a conductor layer are laminated on a transparent substrate made of a flexible resin such as glass or polyimide.

As illustrated in FIG. 1, the mother panel 100 includes a plurality of display panel regions 1. The display panel region 1 is a region that becomes a display panel by being cut out from the mother panel 100. The display panel regions 1 are two-dimensionally arranged and are adjacent to each other with a planned cutting line 9 in between. That is, the display panel regions 1 are partitioned by the planned cutting line 9.

The planned cutting line 9 is not a line actually existing on the mother panel 100 but an imaginary line scheduled to be cut in a panel cutting process.

As illustrated in FIG. 2, each display panel region 1 included in the mother panel 100 includes a display region 10 and four edge portions 13, 15, 17, and 19 surrounding the display region 10. The display region 10 is configured to display a full-color image by forming full-color pixels by combining unit pixels (sub-pixels) composed of a plurality of colors, for example, red, green, and blue.

In the following description, a direction in which the edge portion 13 is positioned with respect to the display region 10 is referred to as a downward direction, a direction in which the edge portion 15 is positioned with respect to the display region 10 is referred to as an upward direction, a direction in which the edge portion 17 is positioned with respect to the display region 10 is referred to as a left direction, and a direction in which the edge portion 19 is positioned with respect to the display region 10 is referred to as a right direction.

In the mother panel 100, the plurality of display panel regions 1 are arranged in the up-and-down direction and the left-and-right direction, respectively. In FIG. 2, among the plurality of display panel regions 1 included in the mother panel 100, only two display panel regions 1A and 1B aligned in the up-and-down direction are illustrated in an enlarged manner. The display panel region 1A is an example of a first display panel region, and the display panel region 1B is an example of a second display panel region.

The display panel regions 1A and 1B are adjacent to each other in the up-and-down direction with the planned cutting line 9 in between. Specifically, the edge portion 13 on a lower side of the display panel region 1A and the edge portion 15 on an upper side of the display panel region 1B are adjacent to each other with the planned cutting line 9 in between. That is, the display panel region 1A and the display panel region 1B are in contact with each other. A boundary between the display panel region 1A and the display panel region 1B corresponds to the planned cutting line 9.

In the display panel regions 1A and 1B, a plurality of terminals 21 (hereinafter also referred to as first terminals 21) aligned along the planned cutting line 9 on the lower edge portion 13 and a plurality of terminals 22 (hereinafter also referred to as second terminals 22) aligned along the planned cutting line 9 on the upper edge portion 15 are provided. A flexible printed circuit (FPC) is connected to the terminals 21 and 22 in an FPC connection process after the panel cutting process.

That is, in this embodiment, a division driving display panel in which the terminals 21 and 22 are allocated to two edge portions of the upper and lower edge portions 13 and 15 is employed. By using the first terminal 21 for driving the lower half of the display region 10 provided on the lower edge portion 13 and the second terminal 22 for driving the upper half of the display region 10 provided on the upper edge portion 15 and simultaneously performing write to the lower half and the upper half of the display region 10, it is possible to ensure the pixel write time even on a high-resolution screen.

For that reason, in the mother panel 100 of this embodiment, the terminals 21 and 22 are aligned on both sides of the planned cutting line 9. That is, the first terminals 21 of the display panel region 1A are aligned above the planned cutting line 9 and the second terminals 22 of the display panel region 1B are aligned below the planned cutting line 9.

As will be described below, in this embodiment, a short ring 3 for electrically connecting these terminals 21 and 22 in the state of the mother panel 100 and for electrically separating these terminals 21 and 22 when the mother panel 100 is cut is provided.

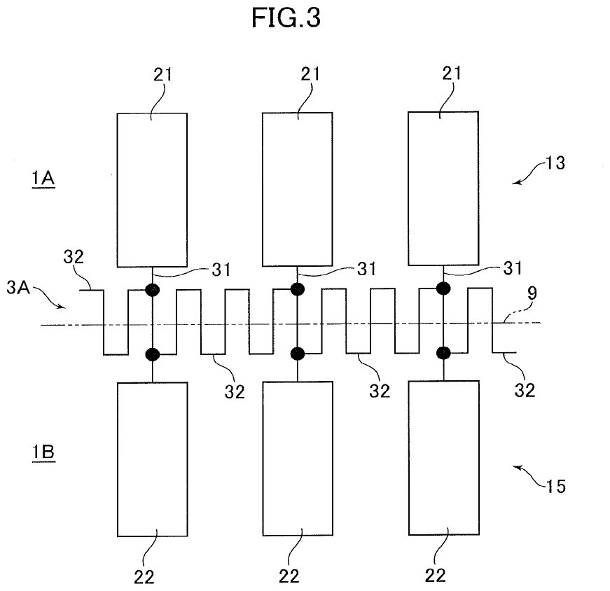

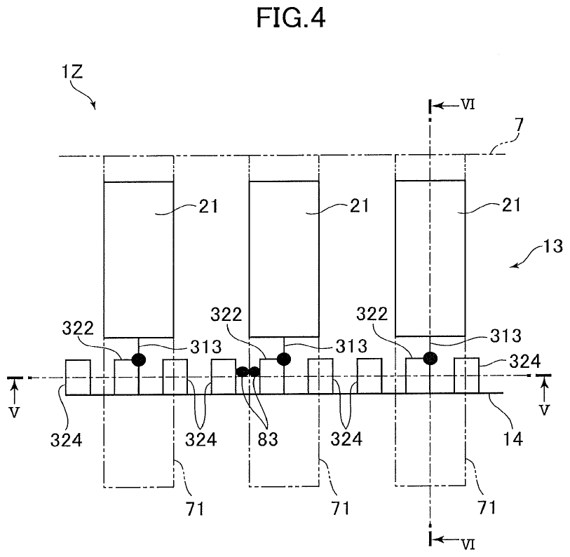

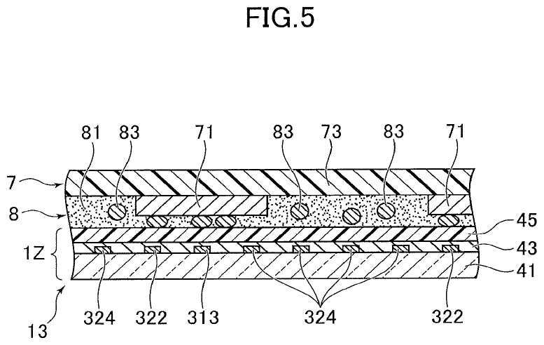

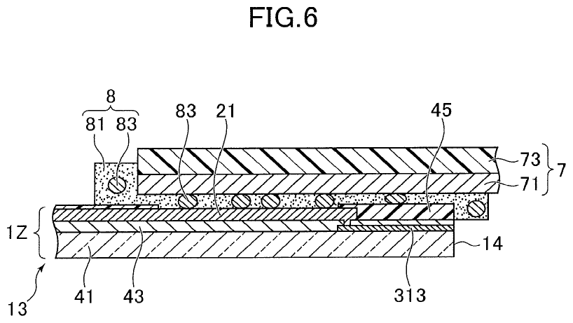

First, a short ring 3A according to a first example will be described. FIG. 3 is a circuit diagram of the short ring 3A, in which the vicinity of the planned cutting line 9 is enlarged. FIG. 4 is a diagram illustrating a state in which an FPC 7 is attached to the edge portion 13 of a display panel 1Z obtained by cutting out the display panel region 1A illustrated in FIG. 3. FIG. 5 is a cross-sectional view cut along line V-V illustrated in FIG. 4. FIG. 6 is a cross-sectional view cut along line VI-VI illustrated in FIG. 4.

The first terminal 21 in the display panel region 1A is spaced upward from the planned cutting line 9 and the second terminal 22 in the display panel region 1B is spaced downward from the planned cutting line 9. The short ring 3A is provided so as to repeatedly cross the planned cutting line 9 in a region between the first terminal 21 and the second terminal 22.

The short ring 3A repeatedly includes a set, which includes a first connection line 31 electrically connecting one of the first terminals 21 and one of the second terminals 22 and a second connection line 32 electrically connecting the one of the first terminals 21 and one adjacent to the one of the second terminals 22, as a minimum unit.

The first connection line 31 crosses the planned cutting line 9 and electrically connects the first terminal 21 and the second terminal 22 closest to the first terminal 21. Specifically, the first connection line 31 electrically connects the first terminal 21 and the second terminal 22 facing each other. The first connection line 31 extends in the up-and-down direction between the first terminal 21 and the second terminal 22 facing each other, and a crossing position where the first connection line 31 crosses the planned cutting line 9 is positioned between the first terminal 21 and the second terminal 22 facing each other. Each end of the first connection line 31 is physically connected to the first terminal 21 and the second terminal 22 facing each other, whereby the first terminal 21 and the second terminal 22 facing each other are electrically connected via the first connection line 31.

The second connection line 32 crosses the planned cutting line 9 and electrically connects the first terminal 21 and the second terminal 22 adjacent to the second terminal 22 closest to the first terminal 21. Specifically, the second connection line 32 electrically connects the first terminal 21 and the second terminal 22 adjacent to the second terminal 22 facing the first terminal 21. A crossing position where the second connection line 32 crosses the planned cutting line 9 is separated in the left-and-right direction from the crossing position where the first connection line 31 crosses the planned cutting line 9. Each end of the second connection line 32 is physically connected to the first connection line 31 and the adjacent first connection line 31, whereby the first terminal 21 and the second terminal 22 adjacent to the second terminal 22 facing the first terminal 21 are electrically connected via the second connection line 32.

The second connection line 32 extends in the left-and-right direction while meandering, that is, extends in the left-and-right direction while reciprocating in the up-and-down direction, and crosses the planned cutting line 9 a plurality of times. In the first example, the second connection line 32 is formed in a rectangular wave shape. A plurality of crossing positions where the second connection line 32 crosses the planned cutting line 9 are present, and the crossing positions are separated from each other in the left-and-right direction. Specifically, the second connection line 32 crosses the planned cutting line 9 an odd number of three or more times. For this reason, both ends of the second connection line 32 are positioned on the opposite sides of the planned cutting line 9. Without being limited to the number of crossings described above, the second connection line 32 may cross the planned cutting line 9 only once, or an even number of times.

The second connection line 32 is provided so that an upward amplitude and a downward amplitude from the planned cutting line 9 are equal to each other. That is, the second connection line 32 is provided so that the planned cutting line 9 passes through a midpoint between a top portion of the upper side and a top portion of the lower side. In the first example, the top portions of the second connection line 32 are line segments extending in the left-and-right direction of the second connection line 32 formed in a rectangular wave shape. The top portion of the upper side of the second connection line 32 is closer to the first terminal 21 than the planned cutting line 9, and the top portion of the lower side of the second connection line 32 is closer to the second terminal 22 than the planned cutting line 9. The second connection line 32 is connected to the first connection line 31 at the top portions.

As illustrated in FIGS. 4 to 6, the FPC 7 is connected to the first terminal 21, which is provided on the lower edge portion 13 of the display panel 1Z cut out from the mother panel 100 in the panel cutting process, in an FPC connection process. Similarly, the FPC (not illustrated) is also connected to the second terminal 22 provided on the upper edge portion 15.

The FPC 7 includes a terminal 71 on one surface of a resin base material 73. The first terminal 21 provided on the display panel 1Z and the terminal 71 provided on the FPC 7 face each other in a layer thickness direction and are connected via an anisotropic conductive film 8. The anisotropic conductive film 8 contains a plurality of conductive particles 83 in a resin film 81, and exhibits insulating properties in an in-plane direction while exhibiting conductivity in the layer thickness direction. The anisotropic conductive film 8 protrudes outside an outer edge of the display panel 1Z and covers a part of an end surface 14 of the display panel 1Z (see FIG. 6).

The plurality of first terminals 21 are aligned along the end surface 14 at the lower edge portion 13 of the display panel 1Z. In a region between the first terminal 21 and the end surface 14, a part of the cut short ring 3A (see FIG. 3) remains.

Specifically, in the region between the first terminal 21 and the end surface 14, first and second connection lines 313 and 322 that are electrically connected to the first terminal 21 and a non-connection line 324 that is not electrically connected to the first terminal 21 are provided. Among the connection and non-connection lines, the first connection line 313 is formed by cutting the first connection line 31 of the short ring 3A illustrated in FIG. 3, and the second connection line 322 and the non-connection line 324 are formed by cutting the second connection line 32 of the short ring 3A illustrated in FIG. 3.

The first connection line 313 extends to the end surface 14 and appears on the end surface 14. The first connection line 313 extends in a straight line, and one end thereof is physically connected to the first terminal 21. The second connection line 322 also extends to the end surface 14 and appears on the end surface 14. The second connection line 322 is bent in an L shape, and one end thereof is physically connected to the first connection line 313. An appearance position where the first connection line 313 appears on the end surface 14 and an appearance position where the second connection line 322 appears on the end surface 14 are separated from each other in the left-and-right direction.

The non-connection line 324 is folded between the first terminal 21 and the end surface 14, and both ends thereof appear on the end surface 14. The non-connection line 324 is folded in a square bracket shape. A plurality of non-connection lines 324 are aligned between the first connection line 313 and the first connection line 313 adjacent thereto. The appearance positions at which the ends of the non-connection line 324 appear on the end surface 14 are separated from each other in the left-and-right direction.

As described above, in the mother panel 100, by forming the second connection line 32 in a wave shape and forming the second connection line 32 so as to cross the planned cutting line 9 a plurality of times (see FIG. 3), it is possible to prevent the second connection line 322 electrically connected to the first terminal 21 from spreading in the left-and-right direction (direction along the end surface 14), in the cut out display panel 1Z.

That is, even when the terminal 71 of the FPC 7 is shifted and disposed, it is possible to prevent a short circuit between the second connection line 322 appearing on the end surface 14 and the terminal 71 of the FPC 7 to be connected to the adjacent first terminal 21 via the conductive particles 83. The second connection line 322 is preferably within the width of the first terminal 21 in the left-and-right direction.

An interval between the second connection line 322 and the non-connection line 324, an interval between the first connection line 313 and the non-connection line 324, or an interval between the non-connection line 324 and the adjacent non-connection line 324, particular, the interval between the lines on the end surface 14 (that is, the interval at which the second connection line 32 crosses the planned cutting line 9 in the mother panel 100) is preferably larger than twice the average particle diameter of the conductive particles 83 contained in the anisotropic conductive film 8.

That is, when the interval between the lines is too narrow, the conductive particles 83 that broke insulating films 43 and 45 may short-circuit adjacent lines, or the conductive particles 83 that have reached the end surface 14 may short-circuit adjacent lines that appear on the end surface 14. It is also assumed that such short-circuiting occurs when two conductive particles 83 are consecutively produced. For that reason, the interval between the lines is preferably larger than twice the average particle diameter of the conductive particles 83.

The first connection line 313, the second connection line 322, and the non-connection line 324 (that is, the first connection line 31 and the second connection line 32 in the mother panel 100) are formed below the insulating film 43 below the first terminal 21. Specifically, the first connection line 313, the second connection line 322, and the non-connection line 324 are formed on a substrate 41, and these lines are covered with the insulating film 43 to form the first terminal 21, and the first terminal 21 is covered with the insulating film 45.

The first terminal 21 is connected to the first connection line 313 through a through-hole formed in the insulating film 43. The first terminal 21 is exposed on the front surface through an opening formed in the insulating film 45. The first connection line 313, the second connection line 322, and the non-connection line 324 are formed of a semiconductor such as polysilicon, for example. These lines are formed simultaneously with a semiconductor layer of a thin film transistor (TFT) provided in the display region 10, for example.

The laminated structure is not limited to the one described above, and another insulating film may be provided between the substrate 41 and the insulating film 43, between the insulating film 43 and the insulating film 45, or on the insulating film 45, for example.

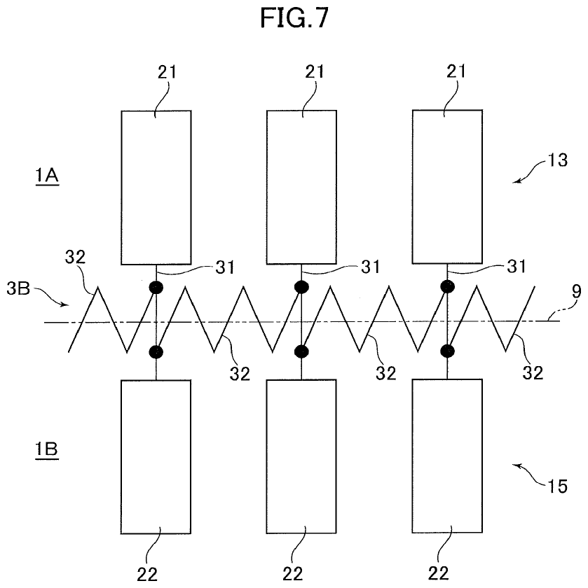

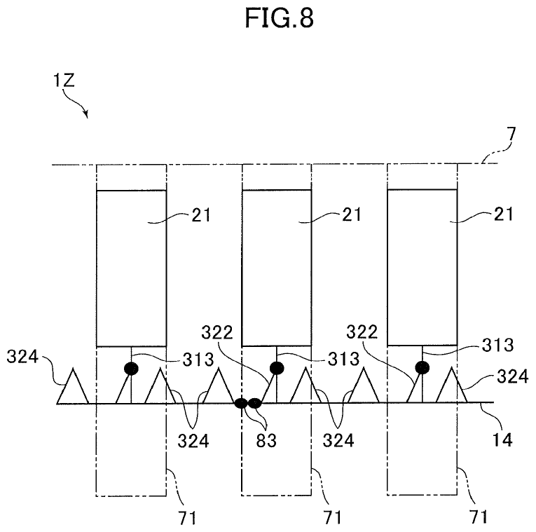

Next, a short ring 3B according to a second example will be described. FIG. 7 is a circuit diagram of the short ring 3B, in which the vicinity of the planned cutting line 9 is enlarged. FIG. 8 is a diagram illustrating a state in which the FPC 7 is attached to the edge portion 13 of the display panel 1Z obtained by cutting out the display panel region 1A illustrated in FIG. 7.

As illustrated in FIG. 7, in the short ring 3B according to the second example, the second connection line 32 is formed in a triangular wave shape. That is, the second connection line 32 is formed by combining a line segment extending obliquely from the lower left to the upper right and a line segment extending obliquely from the upper left to the lower right. In the second example, the top portion of the second connection line 32 is a corner (hereinafter also referred to as a peak) at which two types of obliquely extending line segments of the second connection line 32 formed in a triangular wave shape meet.

As illustrated in FIG. 8, a part of the cut short ring 3B remains in the region between the first terminal 21 and the end surface 14 of the display panel 1Z. Specifically, the second connection line 322 extends obliquely from the first connection line 313 and appears on the end surface 14. The non-connection line 324 is folded back in a V shape and both ends thereof appear on the end surface 14. The interval between the lines on the end surface 14 is preferably larger than twice the average particle diameter of the conductive particles 83 as described above.

By forming the second connection line 32 in a triangular wave shape in the mother panel 100 as in the second example, the interval between the second connection line 322 and the non-connection line 324, the interval between the first connection line 313 and the non-connection line 324 or the interval between the non-connection line 324 and the adjacent non-connection line 324 increases as the distance from the end face 14 in the cut out display panel 1Z increases, so that it is possible to prevent the conductive particles 83 from breaking the insulating films 43 and 45 and short-circuiting adjacent lines.

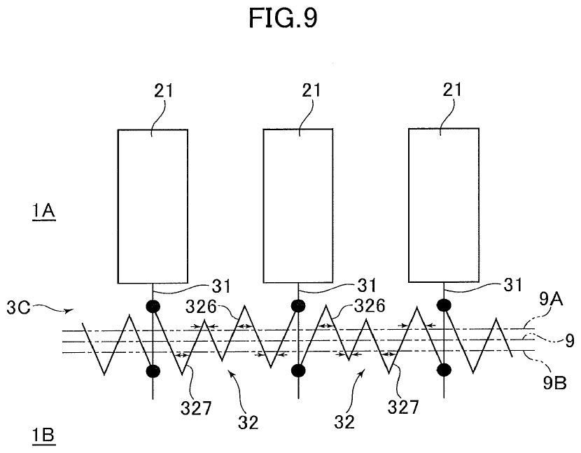

FIG. 9 is a circuit diagram illustrating a short ring 3C according to a modification. In the panel cutting process, the mother panel 100 is cut with the planned cutting line 9 as a target, but the actual cutting position may be shifted from the planned cutting line 9 as in 9A or 9B. In this case, in the short ring 3B according to the second example described above, the interval between the lines on the end surface 14 may be narrower than a desired value.

Therefore, in the short ring 3C according to this modification, first peak portions 326 that protrude longer than other peak portions on the upper side and second peak portions 327 that protrude longer than other peak portions on the lower side are provided on the second connection line 32 having a triangular wave shape. With this configuration, even if the actual cutting position is shifted from the planned cutting line 9, the interval between the lines is secured at any position.

The embodiments of the present invention have been described as above, but the present invention is not limited to the embodiments described above, and various modifications may be made thereto by those skilled in the art.

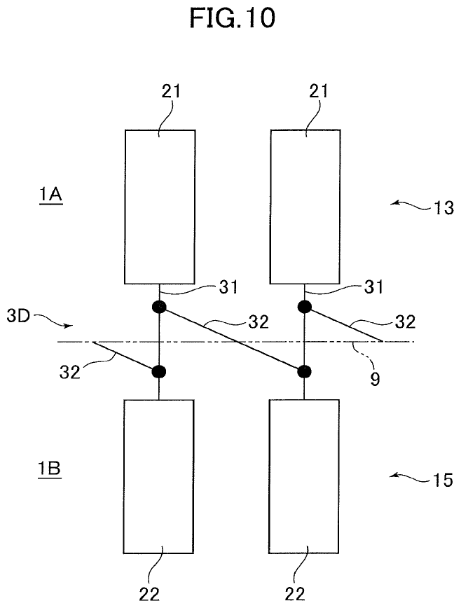

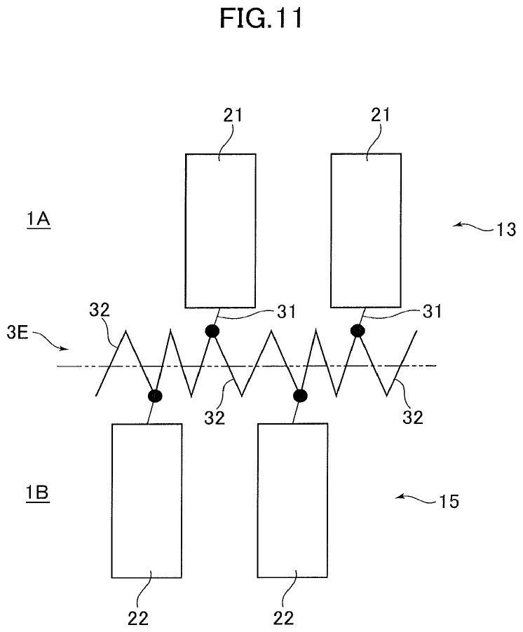

For example, as in a short ring 3D illustrated in FIG. 10, the second connection line 32 may be formed in a straight line in an oblique direction so as to cross the planned cutting line 9 only once. As illustrated in FIG. 11, the terminals 21 and 22 may be disposed in a staggered manner, and the first connection line 31 may be formed in a wave shape similarly to the second connection line 32.

In this embodiment, the case of an organic EL display device has been exemplified as a disclosure example, but as other application examples, all flat panel display devices such as liquid crystal display devices, other self-luminous display devices, or electronic paper display devices having electrophoretic elements are included. Moreover, it cannot be overemphasized that it can apply, without specifically limiting from a small and medium size to a large size.

In the scope of the technical idea of the present invention, those skilled in the art can conceive various changes and modifications, and it is understood that these changes and modifications also belong to the scope of the present invention. For example, for each of the embodiments described above, appropriate addition, deletion, or design changes of constitutional elements, or addition, omission, or changes in conditions of processes performed by those skilled in the art are also within the scope of the invention as long as they include the gist of the invention.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A method of manufacturing a display device comprising:
preparing a mother panel, the mother panel including
a first display panel region and a second display panel region in contact with the first display panel region,
a plurality of first terminals that are positioned at a first edge portion of the first display panel region adjacent to the second display panel region and aligned along a boundary between the first display panel region and the second display panel region,
a plurality of second terminals that are positioned at a second edge portion of the second display panel region adjacent to the first display panel region and aligned along the boundary,
a first connection line that crosses the boundary at a first crossing position and electrically connects one of the plurality of first terminals and one of the plurality of second terminals, and
a second connection line that crosses the boundary at a second crossing position away from the first crossing position and electrically connects the one of the plurality of first terminals and one positioned next to the one of the plurality of second terminals; and
cutting the mother panel at the boundary.

2. The method of manufacturing the display device according to claim 1, wherein
the second connection line crosses the boundary a plurality of times.

3. The method of manufacturing the display device according to claim 1, wherein
the second connection line crosses the boundary an odd number of three or more times.

4. The method of manufacturing the display device according to claim 2, wherein
the second connection line is formed in a rectangular wave shape.

5. The method of manufacturing the display device according to claim 2, wherein
the second connection line is formed in a triangular wave shape.

6. The method of manufacturing the display device according to claim 5, wherein
the second connection line includes first peak portions protruding longer than other peak portions on the first terminal side and second peak portions protruding longer than other peak portions on the second terminal side.

7. The method of manufacturing the display device according to claim 2, further comprising:
connecting a flexible printed circuit board to the plurality of first terminals via an anisotropic conductive film containing conductive particles in a resin film, wherein
an interval at which the second connection line crosses the planned cutting line is larger than twice an average particle diameter of the conductive particles.

8. The method of manufacturing the display device according to claim 1, wherein
the mother panel further includes
a third display panel region that is in contact with the first display panel region on a side opposite to the second display panel region with respect to the first display panel region,
a plurality of third terminals that are positioned at a third edge portion of the first display panel region adjacent to the third display panel region and aligned along a second boundary between the first display panel region and the third display panel region,
a plurality of fourth terminals that are positioned at a fourth edge portion of the third display panel region adjacent to the first display panel region and aligned along the second boundary,
a third connection line that crosses the second boundary at a third crossing position and electrically connects one of the plurality of third terminals and one of the plurality of fourth terminals, and
a fourth connection line that crosses the second boundary at a fourth crossing position away from the third crossing position and electrically connects the one of the plurality of third terminals and one positioned next to the one of the plurality of fourth terminals.

9. The method of manufacturing the display device according to claim 1, wherein
the first connection line is connected to the first terminal and the second terminal, and the second connection line is connected to the first connection line.

10. The method of manufacturing the display device according to claim 1, wherein
the first terminal and the second terminal are formed on an insulating film covering the first connection line and the second connection line.

11. The method of manufacturing the display device according to claim 1, wherein
the first connection line and the second connection line are formed of a semiconductor.

12. A display device comprising:
a plurality of first terminals that are aligned along an end surface at an edge portion of a display panel;
a first connection line that is electrically connected to one of the plurality of first terminals, extends to the end surface, and is in contact with the end surface at a first position; and
a second connection line that is electrically connected to the one of the plurality of first terminals, extends to the end surface, and is in contact with the end surface at a second position away from the first position.

13. The display device according to claim 12, wherein
the second connection line extends from the end surface to the first connection line, and is electrically connected to the one of the plurality of first terminals via the first connection line.

14. The display device according to claim 13, wherein
the second connection line is in contact with a first region extending from the end surface in a first direction, and extends from an end portion of the first region opposite to the end surface in a second direction intersecting the first direction and is in contact with the first connection line.

15. The display device according to claim 12, wherein
a distance between the first position and the second position is smaller than a width of the first terminal in a direction in which the plurality of first terminals are aligned.

16. The display device according to claim 12, wherein
the one of the plurality of first terminals has a first side in contact with the first connection line,
the first side has a contact portion in contact with the first connection line, and
a distance between the first position and the second position is smaller than a distance between an end portion of the first side and the contact portion.

17. The display device according to claim 12, further comprising:
a non-connection line which is not electrically connected to the plurality of first terminals, is folded between the plurality of first terminals and the end surface, and of which both ends are in contact with the end surface.

18. The display device according to claim 12, further comprising:
a plurality of second terminals that are aligned along a second end surface at an edge portion opposite to the edge portion of the display panel;
a third connection line that is electrically connected to one of the plurality of second terminals, extends to the second end surface, and is in contact with the second end surface at a third position; and
a fourth connection line that is electrically connected to the one of the plurality of second terminals, extends to the second end surface, and is in contact with the second end surface at a fourth position away from the third position.

19. The display device according to claim 12, wherein
the first terminal and the second terminal are formed on an insulating film covering the first connection line and the second connection line.
